(19) United States
(12) Patent Application Publication
(10) Pub. No.: US 2012/0044655 A1
(43) Pub. Date: Feb. 23, 2012

(54) GPS-Timing Module

(76) Inventor: George Nichols, Ashley, PA (US)

(21) Appl. No.: 12/860,472

(22) Filed: Aug. 20, 2010

(51) Int. Cl. H05K 1/18

(52) U.S. Cl. 361/748

(57) ABSTRACT

A GPS-timing module for a wireless communication system comprises an “in line” power-over-Ethernet system and a modular surge protection means for protecting the device and a connected wireless access point/backhauls from power or Ethernet surges. The “in line” Power-over-Ethernet system allows the GPS-timing device to directly power the wireless access point/backhaul to which it is providing a GPS-timing signal. The modular surge protection means comprises a removable component that can be quickly replaced following a power surge. The GPS-timing module further comprises a plurality of DIP switches. The DIP switches allow a user to turn the GPS-timing module on and off, turn the communication module on or off, switch between the GPS-timing module's internal GPS-antenna and external GPS-antenna, and remotely revert the communication module to it “default” mode from its “normal” mode.

### CROSS-REFERENCE TO RELATED APPLICATIONS

Not Applicable.

### STATEMENT REGARDING FEDERALLY SPONSORED RESEARCH

Not Applicable.

### BACKGROUND

1. Field of the Invention

The invention relates to the field of wireless communication technology. In particular, the invention relates to electronic devices that are used to synchronize wireless access points and backhauls.

2. Description of the Related Art

A wireless communication system facilitates two-way communication between devices that transfer electromagnetic signals without the use of enhanced electrical conductors (i.e., wires). Wireless communication systems are well known in which a wireless access point transmits electromagnetic signals to, and receives electromagnetic signals from, one or more subscriber modules that are physically aimed at the access point. The access point is attached to a fixed network structure (typically via cable), thereby allowing communications received through the network to be transmitted to the subscriber modules, and vice versa. Examples of such systems include cellular telephone systems and wireless local area network systems.

Since wireless communication systems use electromagnetic signals to deliver information from place to place, such systems must taken into account the interference that can be created when two or more devices use the same or adjacent frequencies. To solve the interference problem, prior-art wireless communication systems use time division multiplexing, frequency division multiplexing, or a combination of both. U.S. Pat. No. 6,016,311 to Gilbert, et al., includes a detailed discussion of these techniques.

The time division multiplexing technique involves the division of uplink and downlink communications into predetermined timeslots. In wireless point to multipoint systems, an access point may assign certain time periods or “slots” to each individual subscriber module in which the subscriber module can send uplink communications to the access point. If all of the subscriber modules attempted to send uplink communications to the access point at the same time, the communications would likely interfere with each other and prevent the information from reaching the access point in clear form. By restricting the subscriber modules to “one-at-a-time” communications, the risk of interference is greatly reduced.

Problems occur when the time used is not identical on all access points, backhauls and subscriber modules. For example, the access point sends a control signal out to all of its subscriber modules informing them that beginning at time 1:00:00, subscriber A will be permitted send uplink transmissions during a first 625 microsecond slot, subscriber B will be permitted to send uplink transmissions during a second 625 microsecond slot immediately following the first slot, and subscriber C will be permitted to send uplink transmissions during a third 625 microsecond slot immediately following the third slot. If the access point and all three subscriber modules understand time 1:00:00 to start that exact same time (i.e., all devices are synchronized with respect to time), then the time-division multiplexing should work at its maximum potential. However, if the devices are not synchronized, one or more subscriber modules may begin its uplink transmissions too early and interfere with the subscriber module that was given the previous slot. Alternatively, a subscriber module may transmit too long and interfere with the subscriber module that was given the next slot. As a result, the subscriber modules interfere with one another and disrupt the uplink transmissions being sent to the access point.

Prior art systems have solved this problem by capturing the time information transmitted by GPS satellites. With each device remotely downloading the same time information, the devices can synchronize and operate using the same time. U.S. Pat. No. 7,133,397 to Jones, et al., describes one approach to a GPS-timing system.

A wireless communication system that makes use of a GPS-timing system to synchronize all of the individual components of the communication system typically use two devices at the transmit end and one device at the receive end of a wireless communication network: the transmit end consists of (1) the communication module (e.g., the access point or backhaul) and (2) the GPS-timing module. The receive end consists of the communication module (e.g., the subscriber module).

Known GPS-timing modules typically comprise a GPS receiver, power input, microprocessor, and an “out” port. An example of a known GPS-timing module is the Motorola® Cluster Management Module 4. An external power source powers the GPS-timing module through a wired connection to the module's input. When powered, the GPS receiver receives a timing signal from one or more GPS satellites, and that timing signal is then sent by the microprocessor through the out port and on to the communication module (typically via a wired connection between the communication module and the GPS-timing module).

One problem with known GPS-timing modules is that they are unable to directly power the communication module (i.e., the communication module requires its own wired connection to an external power source). If a user intends to mount both the GPS-timing module and the communication module to a 150-foot tower, it adds to the user's time and materials to run three separate electrical wires (Ethernet, GPS-timing, and power) from the modules to the base of the tower and connect the modules to an external power source.

Another problem with known GPS-timing modules is that they are typically only designed to serve a plurality of access points or backhaul located at the same location (i.e., a “cluster”). Cellular network operators and large, wireless internet providers typically mount clusters to the tops of towers and buildings to send their distribution signals in as many directions as possible. Accordingly, such providers are able to make full use of known GPS-timing modules' capacity. However, the end user of wireless communications needs only a single access point or backhaul. The cluster capacity built in to known GPS-timing modules goes unused and forces the end user to spend more money on the module than he/she would otherwise need to.

Yet a further problem with known GPS-timing modules is the fact that they offer little to no surge protection for the communication module. Lightning strikes are a common event for communication modules since they are typically mounted high off the ground. Moreover, the known GPS-timing modules that do provide some level of surge protection do so using surge-protection means that is built directly into the circuit board for the module, thereafter requiring complete replacement of the module following a surge.

Additional problems with known GPS-timing modules include the fact that they typically lack antenna options for receiving the GPS-timing signal and lack any ability to control the communication module. Depending on how the user intends to mount the GPS-timing module in his/her wireless communication system, the user may want to use an internal antenna or an external antenna. Moreover, many users position the GPS-timing module at ground level while elevating the communication module. Since known GPS-timing modules do not provide any means of controlling the communication module, users typically have to climb and reach the communication module in order to make changes, or to reset the communications module itself.

There is therefore a need for a GPS-timing module that works “in line” with the communication module's power connection, is designed to serve a single communication module, offers built-in and easy-to-replace surge protection, provides a plurality of antenna options, and provides a means to remotely control certain functions of the communication module.

### SUMMARY

The present invention is directed to a novel GPS-timing module that satisfies the need for an “in line” GPS-timing module that is designed to serve a single communication module, offer comprehensive surge protection, provide a plurality of antenna options, and provide a means to remotely control certain functions of the communication module. A GPS-timing module having features of the present invention comprises a Power-over-Ethernet (“POE”) power supply means, an integrated GPS antenna and external antenna port, a modular surge-protection means, and a plurality of DIP switches wired to control certain functions for the communications module. The POE power supply means enables a GPS-timing module having features of the present invention to send power received from an external power source directly to the communication module, thereby eliminating the need for double wiring. The integrated GPS antenna and external antenna port provides flexibility to the user with respect to receiving a signal from GPS satellites. The modular surge-protection means protects the user's equipment from power and Ethernet surges while allowing the user to easily and cheaply restart his/her equipment following the surge by replacing only the surge-protection means. Finally, the plurality of DIP switches allow the user to accomplish tasks such as switching from an external antenna to the module's internal antenna, resetting the communication module to its original settings, and powering off the communication module.

### BRIEF DESCRIPTION OF DRAWINGS

FIG. 1 is a perspective view of a GPS-timing module embodying features of the present invention.

### DETAILED DESCRIPTION

In the Summary above, and in the Detailed Description and the Claims below, reference is made to particular features of the invention. It is to be understood that the disclosure of the invention in this specification includes all appropriate combinations of such particular features. For example, where a particular feature is disclosed in the context of a particular embodiment or a particular claim, that feature can also be used, to the extent appropriate, in the context of other particular embodiments and claims, and in the invention generally.

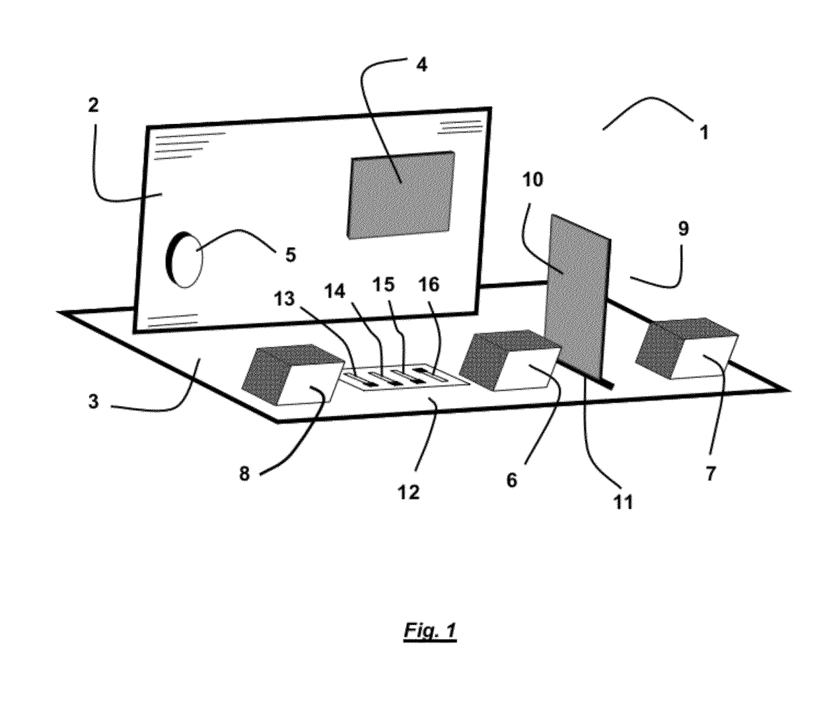

As shown in FIG. 1, a GPS-timing module 1 having features of the present invention comprises two circuit boards, a top circuit board 2 and a bottom circuit board 3. Both the top circuit board 2 and the bottom circuit board 3 can be any known circuit boards, and preferred embodiments of the invention use silk-screen printing-produced circuit boards. In preferred embodiments of the invention, such as the one shown in FIG. 1, the top circuit board 2 is perpendicularly connected to the bottom circuit board 3. The top circuit board 2 is comprised of an internal GPS antenna 4 and an external GPS-antenna port 5. The internal GPS antenna 4 can be any commercially-available GPS antenna module, and preferred embodiments of the invention use the Linx RXM-GPS-S6 module manufactured by Linx.

The bottom circuit board 3 is comprised of a plurality of jacks 6-8. An Ethernet/power “in” jack 6 is positioned on the top of the bottom circuit board 3. The Ethernet/power “in” jack 6 can be any commercially-available modular jack that is capable of receiving electrical signals and power, and preferred embodiments of the invention use an 8P8C jack. The Ethernet/power “out” jack 7 is also positioned on the top of the bottom circuit board 3 and is wired in parallel with the Ethernet/power “in” jack 6. The Ethernet/power “out” jack 7 can be any commercially-available modular jack that is capable of transmitting electrical signals and power, and preferred embodiments of the invention use an 8P8C jack.

The GPS-timing “out” jack 8 is positioned on the top of the bottom circuit board 3. The GPS-timing “out” jack 8 can be any commercially-available modular jack that is capable of transmitting electrical signals. The GPS-timing “out” jack 8 is electrically connected in parallel with the both internal GPS antenna 4 and an external GPS-antenna port 5.

When in use, the Ethernet/power “in” jack 6 receives both electronic communications from an external fixed network and electrical power from an external power supply. The Ethernet/power “in” jack 6 sends a portion of the electrical power it receives to the GPS antenna 4 and external GPS-antenna port 5, thereby energizing the GPS antenna 4 or external GPS-antenna, depending on which the user is using at the time. The GPS antenna (either internal 4 or external) collects the timing signal broadcast by one or more GPS satellites. The timing signal is then transmitted through the GPS-timing “out” jack 8 to the communication module via a wired connection.

The electrical power received by the Ethernet/power “in” jack 6 which is not sent on to the GPS antenna 4 and external GPS-antenna port 5 is sent through the bottom circuit board 3 to the Ethernet/power “out” jack 7. In addition, the electronic communications from an external fixed network received by the Ethernet/power “in” jack 6 are sent through the bottom circuit board 3 to the Ethernet/power “out” jack 7. From there, the power and communications are transmitted from the Ethernet/power “out” jack 7 to the communication module via a wired connection.

As shown in FIG. 1, a GPS-timing module 1 having features of the present invention further comprises a modular surge protection means 9. The modular surge protection means 9 is comprised of a detachable riser card 10 inserted into a transient voltage suppressor diode (“TVS diode”) 11. The modular surge protection means 9 is connected in parallel and adjacent to the Ethernet/power “in” jack 6.

The use of a TVS diode array is well known in the art for suppressing power and Ethernet surges. However, the novel use of the riser card 10 allows a user to quickly and inexpensively return the wireless communication system to a functional state. In known communication modules and GPS-timing modules, the TVS diode array is fully integrated into the circuit board of the modules, thereby requiring either the replacement of the entire circuit board or delicate, exact repair of the circuit board. With the present invention, when a power or Ethernet surge is transmitted through the GPS-timing module 1, the surge causes the riser card 10 to fail, thereby protecting the remaining components of the GPS-timing module 1, as well as the communication module itself. To restart the GPS-timing module 1, the user simply removes the failed riser card 10 from the TVS diode 11 and replaces it. The riser card 10 is constructed out of standard circuit board materials, and is preferably comprised of a 48v fuse.

As shown in FIG. 1, a GPS-timing module 1 having features of the present invention further comprises a plurality of DIP switches 12. DIP switches 12 are well known and any commercially-available DIP switches can be used in the present invention. The first DIP switch 13 allows the user to turn on or turn off the GPS-timing module 1 itself. The second DIP switch 14 allows the user to remotely turn on or turn off the communication module. The third DIP switch 15 allows the user to switch from using the GPS internal antenna 4 to the external GPS-antenna that is connected to the GPS-timing module 1 through the external GPS-antenna port 5, and vice versa. The fourth DIP switch 16 allows the user to remotely revert the communication module back to its “default” mode from its “normal” mode. This last feature of the present invention allows a user who has mounted the GPS-timing module 1 at ground level to forgo climbing to the communication module in order to return that module to its “default” mode for purposes of reprogramming the communication module's software.

What is claimed is:

1. A GPS-timing device, comprising:
(a) a top circuit board, said top circuit board comprising (i) a GPS antenna, and (ii) a port for an external GPS antenna;
(b) a bottom circuit board;
(c) at least one Power-over-Ethernet “in” jack;
(d) at least one Power-over-Ethernet “out” jack;
(e) at least one GPS-timing signal jack;
(f) a plurality of DIP switches; and
(g) a modular surge protection means.

2. The GPS-timing device of claim 1, wherein said Power-over-Ethernet “in” jack and said Power-over-Ethernet “out” jack are 8P8C jacks.

3. The GPS-timing device of claim 1, wherein said plurality of DIP switches is comprised of four DIP switches.

4. The GPS-timing device of claim 1, wherein said top circuit board and said bottom circuit board are produced using a silk-screen printing process.

5. The GPS-timing device of claim 1, wherein said modular surge protection means comprises a removable riser card.
